(19) United States
(12) Patent Application Publication
(10) Pub. No.: US 2020/0168390 A1
(43) Pub. Date: May 28, 2020

(54) ELECTRICAL COMPONENT AND ELECTRICAL DEVICE

(71) Applicant: YAMAHA CORPORATION, Hamamatsu-shi (JP)

(72) Inventor: Katsumi SUZUKI, Hamamatsu-shi (JP)

(21) Appl. No.: 16/675,593

(22) Filed: Nov. 6, 2019

(30) Foreign Application Priority Data
Nov. 22, 2018 (JP) 2018-219462

(51) Int. Cl. H01F 27/28; H01F 27/08; H05K 7/20; H01F 37/00; H01F 27/29; H01F 17/06

(52) U.S. Cl. CPC H01F 27/2876; H01F 27/08; H01F 17/06; H01F 37/00; H01F 27/292; H05K 7/20

(57) ABSTRACT

An electrical component includes a base that is electrically insulating and has a thermal conductivity of at least 1 W/mK; a core part mounted on the base; and a coil wound around part of the core part.

### CROSS REFERENCE TO RELATED APPLICATION

This Application claims priority from Japanese Patent Application No. 2018-219462, filed Nov. 22, 2018, the entire contents of which are incorporated herein by reference.

### BACKGROUND OF THE INVENTION

### Field of the Invention

The present invention relates to a technique for dissipating heat generated in a coil.

### Description of Related Art

Techniques for dissipating heat generated in a coil have been proposed in the past. For example, Japanese Patent Application Laid-Open Publication No. 2015-188016 (hereinafter, Patent Document 1) discloses a heat-dissipating structure for a coil. In this heat-dissipating structure, heat generated in the coil is dissipated from an upper side of the coil. Specifically, the heat-dissipating structure includes a heat-dissipating sheet and a metal lid member. The heat-dissipating structure is electrically insulating and covers an upper surface of the coil. The metal lid member is disposed on the other side opposite to the coil with the heat-dissipating sheet interposed therebetween. Heat generated by the coil is dissipated by the heat-dissipating sheet and the metal lid member.

However, the technique of Patent Document 1 has a problem in that the heat-dissipating structure is enlarged because the electrically insulating heat-dissipating sheet and the lid member for heat-dissipating are above the coil.

### SUMMARY

In view of the above-described circumstances, an object of the present invention is to reduce the size of a heat-dissipating structure of a coil.

In order to solve the above-described problem, an electrical component according to an aspect of the present invention includes: a base that is electrically insulating and has a thermal conductivity of at least 1 W/mK; a core part mounted on the base; and a coil wound around part of the core part.

An electrical device according to an aspect of the present invention includes: a substrate including a wiring; and an electrical component mounted on the substrate with the wiring electrically connected to the electrical component, in which, the electrical component includes: a base that is electrically insulating and has a thermal conductivity of at least 1 W/mK; a core part mounted on the base; and a coil wound around part of the core part and electrically connected to the wiring.

### BRIEF DESCRIPTION OF THE DRAWINGS

FIG. 1 is a perspective view showing a partial internal structure of an electrical device according to a first embodiment.

FIG. 2 is a cross-sectional view of an electrical component.

FIG. 3 is a cross-sectional view of an electrical component according to a second embodiment.

### DESCRIPTION OF THE EMBODIMENTS

### First Embodiment

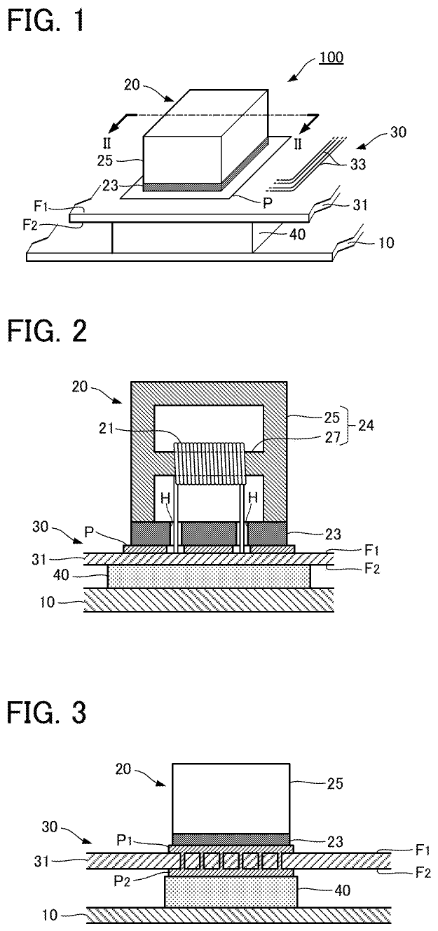

FIG. 1 is a perspective view showing a partial internal structure of an electrical device 100 according to a first embodiment of the present invention. The electrical device 100 is, for example, an amplifying device that amplifies an acoustic signal or a power source device that generates power. The electrical device 100 includes a casing part 10 that houses circuit elements. The casing part 10 has a substantially rectangular parallelepiped hollow structure formed of a metal. For example, the casing part 10 may be used as a heat sink. As shown in FIG. 1, the casing part 10 is provided thereinside with an electrical component 20, a wiring board 30 (for example, a printed board), and a heat-dissipating member 40.

FIG. 2 is a cross-sectional view taken along line II-II of the electrical component 20 of FIG. 1. For example, the electrical component 20 is an electrical component that is used as a choke coil in a filter circuit or a transformer circuit. As shown in FIGS. 1 and 2, the electrical component 20 is mounted on the wiring board 30. As shown in FIG. 2, the electrical component 20 includes a coil 21, a base 23, and a core part 24. The core part 24 includes a casing part 25 and a columnar part 27. The casing part 25 is a substantially hollow rectangular parallelepiped structure. The casing part 25 has an opening portion on the wiring board 30 side. The base 23 is mounted to close the opening of the casing part 25. The casing part 25 houses thereinside the coil 21 and the columnar part 27. The casing part 25 may be configured with several members provided separately from each other.

The coil 21 is, for example, an electric wire wound in a spiral shape. As shown in FIG. 2, for example, the coil 21 is wound around a cylindrical columnar part 27. The columnar part 27 is formed of, for example, a magnetic material. The casing part 25 has wall surfaces facing each other, and the columnar part 27 is mounted between that wall surfaces. In the first embodiment, the casing part 25 and the columnar part 27 are integrally formed. If the casing part 25 and the columnar part 27 are formed separately, material for the casing part 25 is freely selectable regardless of the material of the columnar part 27.

The base 23 is a plate-shaped member. The base 23 is formed of an electrically insulating material having a high thermal conductivity. Specifically, the base 23 is formed of an electrically insulating material having a thermal conductivity of at least 1 W/mK. For example, the base 23 may be formed of a high thermal conductivity resin, the thermal conductivity of which ranges from 1 W/mK to 20 W/mK, inclusive. Alternatively, the base 23 may be formed of a high thermal conductivity ceramic, the thermal conductivity of which ranges from 20 W/mK to 150 W/mK, inclusive. The high thermal conductivity resin is, for example, a resin in which a resin material such as polycarbonate (PC), polybutylene terephthalate (PBT), polyethylene terephthalate (PET), or of flame retardant type 4 (FR4) is mixed with a thermally conductive filler (for example, ceramic particles). The high thermal conductivity ceramic is, for example, an aluminum nitride (AlN) or an aluminum oxide (Al₂O₃). As shown in FIG. 2, the coil 21 is mounted on the base 23. The coil 21 and the core part 24 generate heat when a current flows therein. Since the base 23 is formed of a material having a high thermal conductivity, heat generated from the coil 21 and the core part 24 is conducted to the base 23.

As shown in FIG. 1, the base 23 of the electrical component 20 is in contact with the wiring board 30. As shown in FIG. 2, the coil 21 has two ends, and the base 23 includes through holes H. One end of the coil 21 is exposed from the inside of the casing part 25 to the outside through a corresponding through hole H. That is, the coil 21 has portions that are exposed to the outside of the casing part 25. These portions serve as a connection terminal.

As shown in FIGS. 1 and 2, the wiring board 30 includes a base body 31 (an example of a substrate), wirings 33, and a heat-dissipating member P. The base body 31 is a plate-shape member formed of an electrically insulating material. A thermal conductivity of the base body 31 is less than that of the base 23. For example, the thermal conductivity of the base body 31 ranges from 0.1 W/mK to 0.4 W/mK, inclusive. The base body 31 includes a first surface F1 on which the electrical component 20 is mounted, and a second surface F2 opposite to the first surface F1. The wirings 33 are disposed on the first surface F1 and the second surface F2. Each of the ends of the coil 21 is electrically connected to, for example, the wiring 33 on the second surface F2 through a corresponding through hole (not shown) in the base body 31. The ends of the coil 21 may be connected to a wiring other than the wiring 33 on the second surface F2.

Furthermore, the heat-dissipating member P is provided in a region of the first surface F1 of the wiring board 30 which overlaps with the base 23. The heat-dissipating member P is formed of a material such as a metal. For example, the heat-dissipating member P may be formed from a conductive layer shared by the wiring 33 on the first surface F1. The heat-dissipating member P is electrically isolated from the wiring 33 and the ends of the coil 21. The base 23 has a surface that faces the first surface F1. This surface of the base 23 is in contact with the heat-dissipating member P. In the first embodiment, the heat-dissipating member P is provided over the entire region of the first surface F1 that overlaps with the base 23. Alternatively, the heat-dissipating member P may be provided in a part of this region. The heat conducted from the coil 21 and the core part 24 to the base 23 is then conducted to the heat-dissipating member P.

As shown in FIG. 1, the heat-dissipating member 40 is mounted so as to be in contact with the surface F2 of the base body 31. The surface F2 is on the opposing side of the base body 31 relative to the base 23. That is, the base body 31 is disposed between the base 23 and the heat-dissipating member P. The heat-dissipating member 40 has two surfaces. One surface of the heat-dissipating member 40 opposite to the base body 31 is in contact with an inner wall surface of the casing part 10. That is, the heat-dissipating member 40 is positioned between the wiring board 30 and the casing part 10. For example, there is used, as the heat-dissipating member 40, a heat-dissipating sheet formed of silicon or an acrylic resin. A thermal conductivity of the heat-dissipating sheet ranges, for example, from 1 W/mK to 10 W/mK, inclusive. Alternatively, the heat-dissipating member 40 may be formed of a metal such as copper (398 W/mK) or aluminum (236 W/mK). In the first embodiment, the heat-dissipating member 40 is provided over the entire region of the second surface F2 of the base body 31 that overlaps with the heat-dissipating member P. If the heat-dissipating member 40 is formed of an electrically insulating material, the heat-dissipating member P may be provided over the entire second surface F2, and the heat-dissipating member P may be connected to the wiring 33. Furthermore, the heat-dissipating member 40 may be provided in a part of a region of the second surface F2 that overlaps with the heat-dissipating member P. The heat conducted from the coil 21 and the core part 24 to the heat-dissipating member P through the base 23 is conducted to the heat-dissipating member 40 through the base body 31. Furthermore, the heat conducted to the heat-dissipating member 40 is dissipated from the casing part 10.

As will be understood from the above description, in the first embodiment, since the coil 21 is mounted on the electrically insulating base 23 having a thermal conductivity of at least 1 W/mK, the base 23 on which the coil 21 is mounted can be used to dissipate heat generated from the coil 21 and the core part 24. Accordingly, for example, it is possible to minimize the size of the heat-dissipating structure of the coil 21 as compared with a configuration in which a member for dissipating heat generated from the coil 21 and the core part 24 are provided separately from the base 23.

For example, it is assumed that there is a configuration in which the base 23 of the electrical component 20 is conductive. In this configuration, the wiring 33 cannot be formed in a portion of the base body 31 with which the base 23 is in contact, and thus, arrangement of the wiring 33 is limited. In contrast, in the first embodiment, since the base 23 is electrically insulating, there is an advantage in that there is reduced influence on the wiring 33 on the base body 31 as compared with the configuration in which the base 23 is electrically conductive.

In the first embodiment, the heat-dissipating member P that is in contact with the base 23 is provided in the region of the base body 31 that overlaps with the base 23. Accordingly, the heat generated in the coil 21 and the core part 24 can be efficiently dissipated from the base 23 via the heat-dissipating member P. Furthermore, in the first embodiment, the heat-dissipating member 40 is in contact with the second surface F2 of the base body 31. Accordingly, there is an advantage in that the heat generated in the coil 21 and the core part 24 can be efficiently dissipated from the base 23 and the base body 31 via the heat-dissipating member 40. According to the configuration of the first embodiment, the casing part 10 is in contact with the surface of the heat-dissipating member 40. This surface is on the opposing side of the second heat-dissipating member 40 relative to the base body 31. That is, the heat-dissipating member 40 is disposed between the base body 31 and the casing part 10. Accordingly, the heat generated in the coil 21 and the core part 24 can be efficiently dissipated from the heat-dissipating member 40 via the casing part 10.

### Second Embodiment

A second embodiment according to the present invention will be described. In the embodiment shown in the following, elements having the same functions as in the first embodiment are denoted by the same respective reference numerals as used for like elements in the description of the first embodiment, and detailed description thereof is omitted where appropriate.

FIG. 3 is a cross-sectional view of an electrical device 100 according to the second embodiment. Detailed illustration of the cross section of the electrical component 20 is omitted. As shown in FIG. 3, in the second embodiment, the heat-dissipating member P is also formed on the second surface F2 in addition to the first surface F1 of the base body 31. For example, a heat-dissipating member P2 may be formed from a conductive layer shared by the wiring 33 on the second surface F2. The heat-dissipating member P1 on the first surface F1 and the heat-dissipating member P2 on the second surface F2 are connected to each other via through holes formed in the base body 31.

The second embodiment realizes an effect equal to or greater than that of the first embodiment. In the second embodiment, the heat-dissipating member P2 is provided on the second surface F2, and is connected to the heat-dissipating member P1. Therefore, the heat conducted from the coil 21 to the base 23 is conducted to the heat-dissipating member 40 through the heat-dissipating member P1 and the heat-dissipating member P2. Thus, as compared with a configuration in which only the heat-dissipating member P1 is formed on the base body 31, there is an advantage in that the heat conducted from the coil 21 and the core part 24 to the base 23 can be efficiently dissipated from the heat-dissipating member P2.

### Modifications

Aspects of specific modifications added to each of the above-exemplified aspects will be described. Two or more modes chosen freely from among the following may also be combined so long as they do not conflict.

(1) In each of the above-described embodiments, although the heat-dissipating members P (P₁, P₂) are formed on the base body 31, the present invention does not require forming the heat-dissipating members P (P₁, P₂) on the base body 31.

(2) In each of the above-described embodiments, although the electrical device 100 includes the heat-dissipating member 40, the present invention does not require providing the electrical device 100 with the heat-dissipating member 40. In the configuration in which the electrical device 100 does not include the heat-dissipating member 40, for example, the heat-dissipating members P (P₁, P₂) may be formed over a region of the first surface F₁ wider than the region overlapping with the base 23. This allows for effective dissipation of heat of the coil 21 and the core part 24.

(3) In each of the above-described embodiments, although the electrical device 100 includes the casing part 10, the present invention does not require providing the electrical device 100 with the casing part 10.

(4) In each of the above-described embodiments, each of the heat-dissipating members P (P1, P2) may be used as a ground line.

### Appendix

For example, the following aspect is understood from the foregoing embodiments.

An electrical component according to an aspect (a first aspect) of the present invention includes: a base that is electrically insulating and has a thermal conductivity of at least 1 W/mK; a core part mounted on the base; and a coil wound around part of the core part.

According to the above aspect, since the coil is mounted on the base that is electrically insulating and has a thermal conductivity of at least 1 W/mK, the base on which the coil is mounted can be used to dissipate heat generated from the coil and the core part. Therefore, for example, it is possible to minimize the size of the heat-dissipating structure of the coil as compared with a configuration in which a member for dissipating the heat generated from the coil and the core part is provided separately from the base.

In an example (a second aspect) of the first aspect, the base is formed of a high thermal conductivity resin. In an example (a third aspect) of the first aspect, the base is formed of a high thermal conductivity ceramic. In an example (a fourth aspect) of the first aspect, the core part includes a casing part and a columnar part. In an example (a fifth aspect) of the fourth aspect, the coil is wound around the columnar part.

An electrical device according to an aspect (a sixth aspect) of the present invention includes: a substrate including a wiring; and an electrical component mounted on the substrate with the wiring electrically connected to the electrical component, in which, the electrical component includes: a base that is electrically insulating and has a thermal conductivity of at least 1 W/mK; a core part mounted on the base; and a coil wound around part of the core part and electrically connected to the wiring.

According to the above-described aspect, since the coil is mounted on the base that is electrically insulating and has a thermal conductivity of at least 1 W/mK, the base on which the coil is mounted can be used to dissipate heat generated from the coil and the core part. Therefore, for example, it is possible to minimize the size of the heat-dissipating structure of the coil as compared with a configuration in which a member for dissipating the heat generated from the coil and the core part is provided separately from the base.

In an example (a seventh aspect) of the sixth aspect further includes a heat-dissipating member that is in contact with the base and disposed in a region of the substrate that overlaps with the base.

According to the above-described aspect, since there is disposed a heat-dissipating member that is in contact with the base in a region of the substrate that overlaps with the base, the heat generated by the coil and the core part can be efficiently dissipated from the base via the heat-dissipating member.

In an example (an eighth aspect) of the sixth aspect further includes a heat-dissipating member that is in contact with a surface of the substrate, in which, the substrate is disposed between the base and the heat-dissipating member.

According to the above-described aspect, a heat-dissipating member is in contact with a surface of the substrate, in which, the substrate is disposed between the base and the heat-dissipating member. Accordingly, the heat generated by the coil and the core part can be efficiently dissipated from the base and the substrate via the second heat-dissipating member.

In an example (a ninth aspect) of the eighth aspect, the core part includes a casing part that is in contact with a surface of the heat-dissipating member, and the heat-dissipating member is disposed between the substrate and the casing part. According to the above-described aspect, since a casing part that is in contact with a surface of the heat-dissipating member, and the heat-dissipating member is disposed between the substrate and the casing part. Accordingly, the heat generated in the coil and the core part can be efficiently dissipated from the heat-dissipating member through the casing part. In an example (a tenth aspect) of the ninth aspect, the core part further includes a columnar part, and the coil is wound around the columnar part.

### DESCRIPTION OF REFERENCE SIGNS

100 . . . Electrical device;

10 . . . Casing part;

20 . . . Electrical component;

21 . . . Coil;

23 . . . Base;

24 . . . Core part;

25 . . . Casing part;

27 . . . Columnar part;

30 . . . Wiring board;

31 . . . Base body;

33 . . . Wiring;

40 . . . Heat-dissipating member;

H . . . Through hole;

P . . . Heat-dissipating member;

What is claimed is:

1. An electrical component comprising:
a base that is electrically insulating and has a thermal conductivity of at least 1 W/mK;
a core part mounted on the base; and
a coil wound around part of the core part.

2. The electrical component according to claim 1, wherein the base is formed of a high thermal conductivity resin.

3. The electrical component according to claim 1, wherein the base is formed of a high thermal conductivity ceramic.

4. The electrical component according to claim 1, wherein the core part includes a casing part and a columnar part.

5. The electrical component according to claim 4, wherein the coil is wound around the columnar part.

6. An electrical device comprising:
a substrate including a wiring; and
an electrical component mounted on the substrate with the wiring electrically connected to the electrical component,
wherein the electrical component includes:
a base that is electrically insulating and has a thermal conductivity of at least 1 W/mK;
a core part mounted on the base; and
a coil wound around part of the core part and electrically connected to the wiring.

7. The electrical device according to claim 6, further comprising a heat-dissipating member that is in contact with the base and disposed in a region of the substrate that overlaps with the base.

8. The electrical device according to claim 6, further comprising:
a heat-dissipating member that is in contact with a surface of the substrate,
wherein the substrate is disposed between the base and the heat-dissipating member.

9. The electrical device according to claim 8, wherein:
the core part includes a casing part that is in contact with a surface of the heat-dissipating member, and
the heat-dissipating member is disposed between the substrate and the casing part.

10. The electrical device according to claim 9, wherein:
the core part further includes a columnar part, and
the coil is wound around the columnar part.
